(19) United States
(12) Patent Application Publication
(10) Pub. No.: US 2024/0182360 A1
(43) Pub. Date: Jun. 6, 2024

(54) WINDOW AND METHOD OF MANUFACTURING THE SAME

(71) Applicant: Samsung Display Co., LTD., Yongin-si (KR)

(72) Inventors: YONGKYU KANG, Yongin-si (KR); Jinsu NAM, Yongin-si (KR); SEUNGHO KIM, Yongin-si (KR)

(21) Appl. No.: 18/527,711

(22) Filed: Dec. 4, 2023

(30) Foreign Application Priority Data
Dec. 5, 2022 (KR) 10-2022-0167320

(51) Int. Cl. C03C 23/00; C03C 21/00

(52) U.S. Cl. CPC C03C 23/0055; C03C 21/002; H05K 5/03

(57) ABSTRACT

A window includes a base glass including a central region, and an exterior region surrounding the central region, and a crystal layer disposed on the base glass and overlapping the exterior region, where the crystal layer includes at least one selected from P₂O₅, ZrO₂, and TiO₂, and a crystal content of the base glass is different from a crystal content of the crystal layer.

This application claims priority to Korean Patent Application No. 10-2022-0167320, filed on Dec. 5, 2022, and all the benefits accruing therefrom under 35 U.S.C. § 119, the content of which in its entirety is herein incorporated by reference.

### BACKGROUND

### 1. Field

Embodiments of the disclosure herein relate to a window and a method of manufacturing the window, and more particularly, to a window including glass with a high crystal content in some regions and a method of manufacturing a window including ion implantation.

### 2. Description of the Related Art

A display device is activated in response to an electrical signal, and typically includes a window, a housing, an electronic element, or the like. The electronic element may include various elements, such as a display element, a touch element, or a detection element, activated in response to electrical signals.

A window may be disposed on a front surface of a display panel to protect electronic elements and to provide an active region to a user. The window may stably protect electronic elements against an external impact. Accordingly, studies are being conducted on a method of strengthening a window exhibiting high strength.

### SUMMARY

Embodiments of the disclosure provide a window with improved durability to an impact.

Embodiment of the disclosure also provide a method of manufacturing a window including ion implantation to improve the durability of the window.

An embodiment of the invention provides a window including: a base glass including a central region, and an exterior region surrounding the central region; and a crystal layer disposed on the base glass and overlapping the exterior region, where the crystal layer includes at least one selected from P₂O₅, ZrO₂, and TiO₂, and a crystal content of the base glass is different from a crystal content of the crystal layer.

In an embodiment, the crystal layer may not overlap the central region.

In an embodiment, the crystal content of the crystal layer may be greater than the crystal content of the base glass.

In an embodiment, a coefficient of thermal expansion of the base glass may be different from a coefficient of thermal expansion of the crystal layer.

In an embodiment, the exterior region may include a corner region adjacent to a vertex of the central region, and the crystal layer may overlap the corner region.

In an embodiment, the crystal layer may have a thickness in a range of about 20 micrometers (μm) to about 100 μm.

In an embodiment, the crystal layer may include: a first inorganic layer disposed on the base glass; and a second inorganic layer disposed on the first inorganic layer, wherein a coefficient of thermal expansion of the first inorganic layer may be different from a coefficient of thermal expansion of the second inorganic layer.

In an embodiment, the crystal layer may further include a third inorganic layer disposed on the second inorganic layer, and a coefficient of thermal expansion of the third inorganic layer may be different from a coefficient of thermal expansion of the second inorganic layer.

In an embodiment, the window may further include a bezel pattern disposed on under the base glass; and a window functional layer disposed on the base glass to cover the crystal layer.

In an embodiment, the bezel pattern may overlap the exterior region.

In an embodiment, the window may have a light transmittance in a range of about 80% to about 100% with respect to light in a wavelength range of about 400 nanometers (nm) to about 700 nm.

In an embodiment of the invention, a method of manufacturing a window includes: providing a preliminary glass substrate including a central region and an exterior region surrounding the central region; and forming a preliminary crystal layer by implanting a nucleating agent into the base glass through ion implantation, where the preliminary crystal layer may overlap the exterior region, and the nucleating agent may include at least one selected from P₂O₅, ZrO₂, and TiO₂.

In an embodiment, the forming the preliminary crystal layer may include: providing a mask over the preliminary glass substrate to cover the central region; and implanting the nucleating agent from above the mask.

In an embodiment, the exterior region may include a corner region adjacent to a vertex of the central region, and the preliminary crystal layer may overlap the corner region.

In an embodiment, the method may further include, after the forming the preliminary crystal layer, performing a thermal treatment on the preliminary crystal layer.

In an embodiment, the preliminary crystal layer may have a thickness in a range of about 20 μm to about 100 μm from an upper surface of the base glass.

In an embodiment, the forming the preliminary crystal layer may include: forming a first preliminary inorganic layer by implanting, into the preliminary glass substrate, a first nucleating agent including at least one selected from P₂O₅, ZrO₂, and TiO₂; and forming a second preliminary inorganic layer by implanting, into the first preliminary inorganic layer, a second nucleating agent including at least one selected from P₂O₅, ZrO₂, and TiO₂.

In an embodiment, a coefficient of thermal expansion of the first preliminary inorganic layer may be different from a coefficient of thermal expansion of the second preliminary inorganic layer.

In an embodiment, the method may further include, after the forming the preliminary crystal layer, chemically strengthening the preliminary glass substrate.

In an embodiment, the chemically strengthening the preliminary glass substrate may include providing a strengthening molten salt to the preliminary glass substrate.

### BRIEF DESCRIPTION OF THE DRAWINGS

The above and other features of the invention will become more apparent by describing in further detail embodiments thereof with reference to the accompanying drawings, in which:

FIG. 1 is a perspective view illustrating a display device according to an embodiment;

FIG. 2 is an exploded perspective view of a display device according to an embodiment;

FIG. 3 is a cross-sectional view illustrating a window according to an embodiment;

FIG. 4 is a plan view illustrating a window according to an embodiment;

FIGS. 5A to 5C are cross-sectional views respectively illustrating windows according to embodiments;

FIGS. 6A and 6B are flowcharts each illustrating a method of manufacturing a window according to an embodiment;

FIG. 6C is a flowchart illustrating some operations of a method of manufacturing a window according to an embodiment;

FIGS. 7A to 7C are cross-sectional views of some operations of a method of manufacturing a window according to an embodiment; and

FIGS. 8A and 8B are cross-sectional views of some operations of a method of manufacturing a window according to an alternative embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, it will be understood that when an element (or region, layer, portion, or the like) is referred to as being “on”, “connected to” or “coupled to” another element, it may be directly connected/coupled to another element, or intervening elements may be disposed therebetween.

Like numbers or symbols refer to like elements throughout. Also, in the drawings, the thicknesses, ratios, and dimensions of the elements are exaggerated for effective description of the technical contents.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the disclosure. The singular forms include the plural forms as well, unless the context clearly indicates otherwise.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Meanwhile, in this specification, it will be understood that the wording “being directly disposed” means that there are no intervening layers, films, regions, plates or the like between a portion of layers, films, regions, plates or the like and another portion. For example, the wording “being directly disposed” may mean to be disposed between two layers or two members without using an additional member such as an adhesive member or like.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skills in the art to which the disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described with reference to the accompanying drawings.

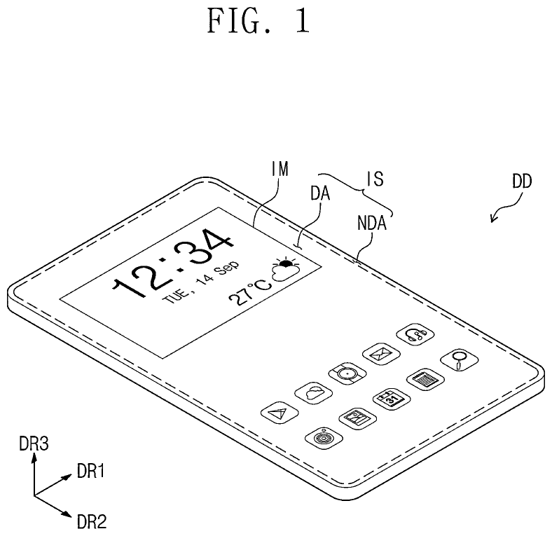

FIG. 1 is a perspective view illustrating a display device according to an embodiment.

A display device DD according to an embodiment may be a device activated in response to an electrical signal. The display device DD may be a flexible device. In an embodiment, for example, the display device DD may be a portable electronic device, a tablet computer, a car navigation system, a game console, a personal computer, a laptop computer, or a wearable device but is not limited thereto. In FIG. 1, an embodiment where the display device DD is a portable electronic device is illustrated as an example.

In an embodiment, the display device DD may display an image IM through a display surface IS. The display surface IS may include a display region DA and a non-display region NDA adjacent to the display region DA. The non-display region NDA may be a region in which the image is not displayed. However, an embodiment of the invention is not limited thereto, and alternatively, the non-display region NDA may be omitted. The display surface IS may be on a plane defined by a first direction DR1 and a second direction DR2.

In this specification, the first direction DR1 and the second direction DR2 may be perpendicular to each other, and a third direction DR3 may be a normal direction of the plane defined by the first direction DR1 and the second direction DR2. A thickness direction of the display device DD may be a direction parallel to the third direction DR3. In this specification, an upper surface (or front surface) and a lower surface (or rear surface) of each member constituting the display device DD may be defined based on the third direction DR3. Here, the directions indicated by the first to third directions DR1, DR2, and DR3 illustrated in the drawings may have a relative concept and may thus be changed to other directions.

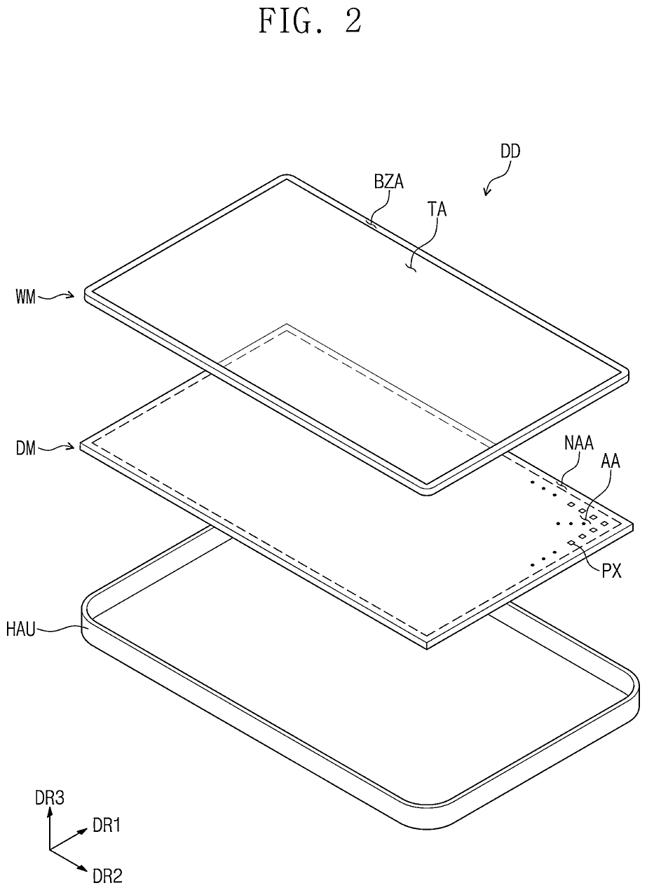

FIG. 2 is an exploded perspective view of a display device according to an embodiment. In an embodiment, a display device DD may include a display module DM and a window WM disposed on an upper portion or a lower portion of the display module DM. FIG. 2 illustrates an embodiment where the window WM is disposed on an upper portion of the display module DM, but this is merely illustrated as an example. The window WM may be disposed on either an upper portion or a lower portion of the display module DM.

In an embodiment, the display device DD may further include a housing HAU that accommodates the display module DM. In an embodiment of the display device DD illustrated in FIGS. 1 and 2, the window WM and the housing HAU may be coupled to constitute the exterior of the display device DD. The housing HAU may be disposed under the display module DM. The housing HAU may include a material having a relatively high stiffness. In an embodiment, for example, the housing HAU may include a plurality of frames and/or plates including or composed of glass, plastic, or metal. The housing HAU may provide or define a predetermined accommodating space. The display module DM may be accommodated inside the accommodating space and protected against an external impact.

The display module DM may be activated in response to an electrical signal. The display module DM may be activated to display the image IM on the display surface IS of the display device DD. In addition, the display module DM may be activated to detect an external input applied to an upper surface. The external input may include user's touch, contact or approach by an intangible material, pressure, light, or heat, but is not limited to any one embodiment.

The display module DM may include an active region AA and a peripheral region NAA. The active region AA may be a region in which the image IM (see FIG. 1) is provided. A pixel PX may be disposed in the active region AA. The peripheral region NAA may be adjacent to the active region AA. The peripheral region NAA may surround the active region AA. A driving circuit, a driving line, or the like for driving the active region AA may be disposed in the peripheral region NAA.

The display module DM may include a plurality of pixels PX. The pixels PX may each display light in response to an electrical signal. The light displayed by the pixels PX may form the image IM. The pixels PX may each include a display element. In an embodiment, for example, the display element may be an organic light-emitting element, a quantum dot light-emitting element, an electrophoretic element, an electrowetting element, or the like.

The window WM may include a transmission region TA and a bezel region BZA. The transmission region TA may overlap at least a portion of the active region AA of the display module DM. The transmission region TA may be an optically transparent region. In an embodiment, for example, the transmission region TA may have a transmittance of about 90% or greater (or higher) with respect to light having a visible light wavelength range. The image IM may be provided to a user through the transmission region TA, and the user may obtain information through the image IM.

The bezel region BZA may be a region having a relatively lower light transmittance than the transmission region TA. The bezel region BZA may define a shape of the transmission region TA. The bezel region BZA may be adjacent to the transmission region TA and surround the transmission region TA.

The bezel region BZA may have a predetermined color. The bezel region BZA may cover the peripheral region NAA of the display module DM, and thus may block the peripheral region NAA from being viewed from the outside. This is exemplarily illustrated, and alternatively, the bezel region BZA may be omitted in the window WM.

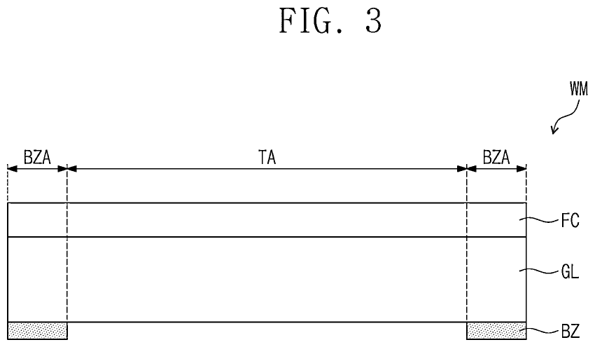

FIG. 3 is a cross-sectional view illustrating a window according to an embodiment.

A window WM according to an embodiment of the invention may include a glass substrate GL, a window functional layer FC disposed on the glass substrate GL, and a bezel pattern BZ disposed under the glass substrate GL.

The window functional layer FC may be disposed on the glass substrate GL. The window functional layer FC may include at least one selected from an anti-fingerprint layer and an anti-reflection layer. The window functional layer FC may include a hard coating layer to protect the window WM against an external impact.

The bezel pattern BZ may be disposed under the glass substrate GL and define the bezel region BZA. The bezel pattern BZ may have a relatively lower light transmittance than the glass substrate GL. In an embodiment, for example, the bezel pattern BZ may have a predetermined color. Accordingly, the bezel pattern BZ may selectively transmit/reflect only light having a predetermined color. Alternatively, the bezel pattern BZ may be a light blocking layer that absorbs incident light. The light transmittance and color of the bezel pattern BZ may be variously provided according to types and shapes of the display device DD (see FIG. 1).

The glass substrate GL may include tempered glass. The glass substrate GL may be subjected to crystallization, thermal strengthening, and chemical strengthening treatments through a window manufacturing method according to an embodiment to be described later. Therefore, the window WM including the glass substrate GL may exhibit high or improved strength.

The glass substrate GL according to an embodiment may have a high transmittance to be used as the cover window in the above-described display device DD (see FIG. 1), and the like. Accordingly, the window WM may have a high transmittance of about 80% or greater with respect to light in a wavelength range of about 400 nanometers (nm) to about 700 nm. In an embodiment, for example, the glass substrate GL according to an embodiment may have a transmittance of about 85% or greater in a wavelength range of visible light, and also have improved impact resistance.

The glass substrate GL according to an embodiment may have a thickness in a range of about 20 micrometers (μm) to about 800 μm. In an embodiment, for example, the glass substrate GL may be have a thickness in a range of about 0.3 mm to about 0.8 mm. That is, the glass substrate GL according to an embodiment may have a thin thickness in a range of about 20 μm to about 800 μm to be used as the cover window of the display device DD (see FIG. 1) according to an embodiment, thereby achieving slimness and lightness of the display device DD (see FIG. 1).

The glass substrate GL may be flat. In addition, the glass substrate GL may be bent or bendable. Although not illustrated, for example, the glass substrate GL may be convexly or concavely bent from a central portion. However, an embodiment of the invention is not limited thereto, and the glass substrate GL may have various shapes.

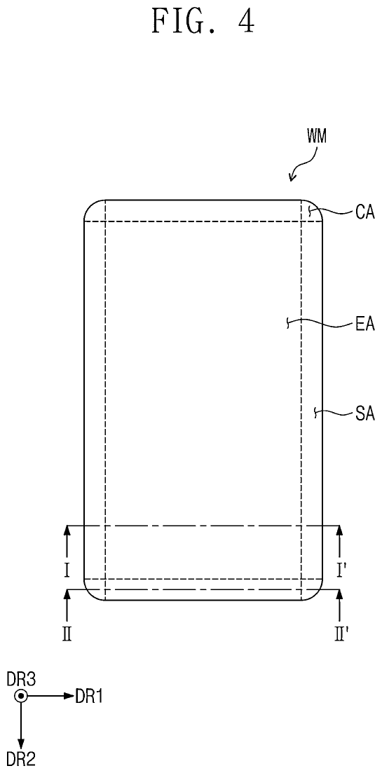

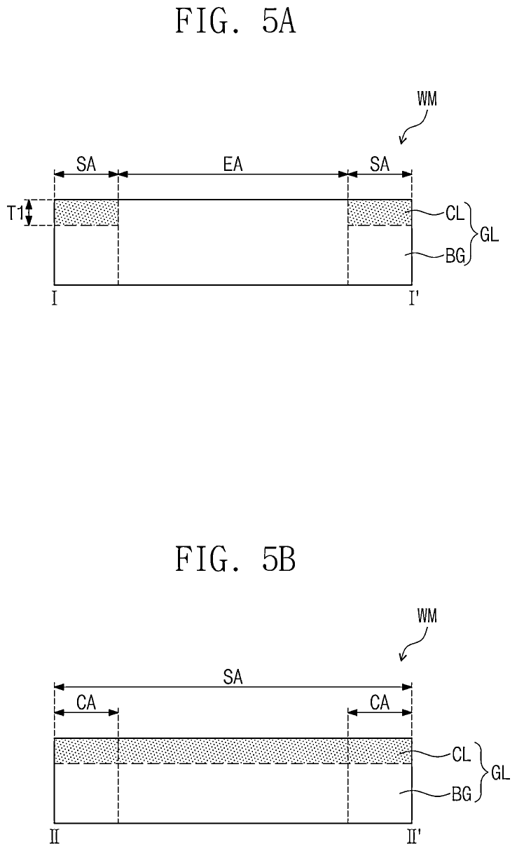

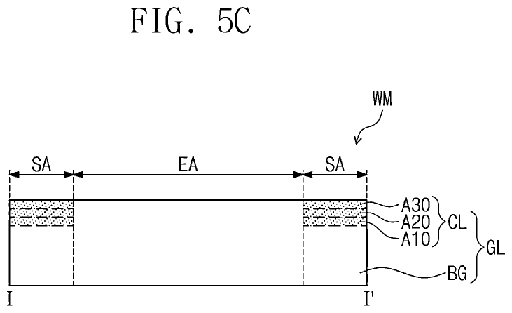

FIG. 4 is a plan view illustrating a window according to an embodiment. FIGS. 5A to 5C are cross-sectional views respectively illustrating windows according to embodiments. FIG. 5A is a cross-sectional view, of the window according to an embodiment, taken along line I-I′ of FIG. 4. FIG. 5B is a cross-sectional view, of the window according to an embodiment the window, taken along line II-II′ of FIG. 4. FIG. 5C is a cross-sectional view, of the window according to an alternative embodiment, taken along line I-I′ of FIG. 4.

Referring to FIG. 4, in a window WM according to an embodiment of the invention, a central region EA and an exterior region SA surrounding the central region EA are defined.

The exterior region SA may be adjacent to the central region EA and surround the central region EA. The exterior region SA may include an edge region of the window WM. Referring to FIGS. 3 and 4, the exterior region SA may include the bezel region BZA in which the bezel pattern BZ is disposed. Alternatively, in an embodiment, the exterior region SA of the window WM may be defined as the bezel region BZA. The central region EA may include the transmission region TA. Alternatively, in an embodiment, the central region EA of the window WM may be defined as the transmission region TA.

The exterior region SA may include corner regions CA adjacent to vertices of the central region EA. In an embodiment, for example, as illustrated in FIG. 4, when a flat surface of the window WM has a quadrilateral shape, the corner regions CA may be defined as four regions spaced apart from each other to correspond to respective four vertices of a quadrangle.

Referring to FIGS. 5A to 5C, a window WM according to an embodiment of the invention may include a base glass BG and a crystal layer CL disposed on the base glass BG. The glass substrate GL according to an embodiment may include the base glass BG and the crystal layer CL disposed on the base glass BG. In an embodiment, the base glass BG and the crystal layer CL may be integrally formed as a single unitary and indivisible part.

The glass substrate GL according to an embodiment may include the base glass BG. The base glass BG may include SiO₂. The base glass BG may further include at least one selected from Al₂O₃, Li₂O, Na₂O, K₂O, MgO, and CaO in addition to SiO₂. In addition, the base glass BG may further include Fe₂O₃, ZnO, TiO₂, P₂O₅, or the like. The base glass BG according to an embodiment may be amorphous solid glass. Alternatively, if desired, at least a portion of the base glass BG according to an alternative embodiment may include a crystalline solid that amorphous glass is crystallized. That is, at least a portion of the base glass BG may be glass-ceramics including an aggregate of fine crystals in glass.

The glass substrate GL according to an embodiment may include the crystal layer CL. The crystal layer CL according to an embodiment may be formed adjacent to an upper surface of the glass substrate GL. The crystal layer CL will be described later in greater detail.

Although not illustrated, the glass substrate GL according to an embodiment may further include a compressive stress layer. The compressive stress layer according to an embodiment may be disposed on the base glass BG and be formed adjacent to an upper surface of the glass substrate GL. The compressive stress layer may be a region spanning from a surface of the glass substrate GL to the location where compressive stress CS becomes 0. In the glass substrate GL according to an embodiment, the crystal layer CL may be included in the compressive stress layer. The thickness of the compressive stress layer may be the same as the thickness of the crystal layer CL, or may be less or greater than the thickness of the crystal layer CL.

Referring to FIGS. 4 and 5A, the crystal layer CL according to an embodiment may overlap the exterior region SA of the window WM and not overlap the central region EA of the window WM. Referring to FIGS. 4 and 5B, the crystal layer CL according to an embodiment may overlap the exterior region SA and the corner regions CA of the window WM. Alternatively, although not shown, in an embodiment, the crystal layer CL may overlap only the corner regions CA in the exterior region SA and not overlap the other region except for the corner regions CA in the exterior region SA. Since the crystal layer CL according to an embodiment is disposed to overlap only the exterior region SA or the corner regions CA, the window WM in the exterior region SA according to an embodiment of the invention may have high surface strength. The occurrence of a crack on a surface of the exterior region SA is reduced, and thus the window WM according to an embodiment of the invention may have high surface impact resistance.

The crystal layer CL according to an embodiment may include at least one selected from P₂O₅, ZrO₂, and TiO₂. The crystal layer CL according to an embodiment may further include SiO₂. The crystal layer CL may include a crystalline solid material. Specifically, the crystal layer CL according to an embodiment may be defined by or composed of a polycrystalline material. The crystal layer CL according to an embodiment may be glass-ceramics including an aggregate of fine crystals in glass. The crystal layer CL may be defined as a region where a portion of materials included in the base glass BG is crystallized. Alternatively, the crystal layer CL according to an embodiment may be defined as a region having a higher crystal content than a crystal content of the base glass BG. In this specification, a crystal content may be defined as a volume fraction of a crystallized portion with respect to a total volume. The crystal layer CL according to an embodiment may be a layer where a portion of materials included in the base glass BG is crystallized by a nucleating agent. The crystal layer CL may be crystallized through a method of manufacturing a window, to be described later, according to an embodiment of the invention.

In the glass substrate GL according to an embodiment, the crystal layer CL and the base glass BG have different crystal contents from each other. In the glass substrate GL according to an embodiment, the crystal content of the crystal layer CL may be higher than the crystal content of the base glass BG. In an embodiment, for example, the crystal layer CL may have a crystal content of about 70 volume percent (vol %) or greater, and the base glass BG may have a crystal content in a range of 0 to about 60 vol %. When the base glass BG has a crystal content of 0, the base glass BG may be amorphous glass. However, the crystal contents of the crystal layer CL and the base glass BG are not limited to the above numerical values and, if desired, may have various numerical values. The crystal content of the crystal layer CL is higher than the crystal content of the base glass BG, and thus the crystal layer CL may have higher strength and higher fracture toughness than the base glass BG. When the crystal layer CL has high fracture toughness, it may mean that the crystal layer CL is highly resistant to fracture.

In the glass substrate GL according to an embodiment, a crystalline phase type of the crystal layer CL may be different from a glass phase type of the base glass BG or a crystalline phase type of the base glass BG. In an embodiment, for example, when the base glass BG according to an embodiment is an amorphous solid, the glass phase of the base glass BG is different from the crystalline phase of the crystal layer CL. Alternatively, when the base glass BG according to an embodiment is a crystalline solid, the base glass BG and the crystal layer CL may have different crystalline phases from each other.

In the glass substrate GL according to an embodiment, the crystal layer CL and the base glass BG may have different coefficients of thermal expansion from each other. In an embodiment, for example, the coefficient of thermal expansion of the crystal layer CL including a crystalline solid may be lower (or less) than the coefficient of thermal expansion of the base glass BG. The coefficient of thermal expansion of the crystal layer CL may vary according to a crystal particle size, etc., included in the crystal layer CL. In the glass substrate GL according to an embodiment, since the crystal layer CL and the base glass BG have different coefficients of thermal expansion from each other, the occurrence of stress and thermal fatigue of the glass substrate GL according to an embodiment may be suppressed, and thus thermal strengthening effect for the glass substrate GL according to an embodiment may be achieved.

Referring to FIG. 5A, the crystal layer CL according to an embodiment may be defined or formed to a predetermined depth in a thickness direction from a surface of the glass substrate GL. A thickness T1 of the crystal layer CL according to an embodiment may correspond to a depth at which a portion of materials included in the base glass BG is crystallized. Alternatively, the thickness T1 of the crystal layer CL according to an embodiment may correspond to a depth of the region having a higher crystal content than the base glass BG. The crystal layer CL according to an embodiment may have a thickness T1 in a range of about 20 μm to about 100 μm. However, the thickness T1 of the crystal layer CL is not limited thereto and may have various values according to a thickness of the glass substrate GL, a thickness of the window WM, a crystalline solid type in the crystal layer CL, or the like.

Referring to FIG. 5C, the crystal layer CL according to an alternative embodiment of the invention may include a plurality of layers separated or distinctive from each other. The crystal layer CL according to an embodiment may include a first inorganic layer A10 disposed on the base glass BG, a second inorganic layer A20 disposed on the first inorganic layer A10, and a third inorganic layer A30 disposed on the second inorganic layer A20. However, an embodiment of the invention is not limited thereto, and the crystal layer CL may include a three or more-layered inorganic layer, or have a single-layered structure.

The first inorganic layer A10, the second inorganic layer A20, and the third inorganic layer A30 may each include a crystalline solid material. The first inorganic layer A10, the second inorganic layer A20, and the third inorganic layer A30 may respectively have different crystal contents. The first inorganic layer A10, the second inorganic layer A20, and the third inorganic layer A30 may be formed to respectively have different crystal contents according to a method of manufacturing a window according to an embodiment of the invention to be described later. In an embodiment, for example, the first inorganic layer A10, the second inorganic layer A20, and the third inorganic layer A30 may include the same material, and the first inorganic layer A10, the second inorganic layer A20, and the third inorganic layer A30 may respectively have different crystal contents according to a difference in sizes of respective crystal particles included in the first inorganic layer A10, the second inorganic layer A20, and the third inorganic layer A30. The second inorganic layer A20 and the third inorganic layer A30 may respectively have different crystal contents since the first inorganic layer A10, the second inorganic layer A20, and the third inorganic layer A30 respectively have different crystallization temperatures. Alternatively, in an embodiment, the first inorganic layer A10, the second inorganic layer A20, and the third inorganic layer A30 may respectively include different crystalline solid materials.

The first inorganic layer A10, the second inorganic layer A20, and the third inorganic layer A30 may respectively have different coefficients of thermal expansion. The coefficient of thermal expansion of the first inorganic layer A10 may be different from the coefficient of thermal expansion of the second inorganic layer A20, and the coefficient of thermal expansion of the second inorganic layer A20 may be different from the coefficient of thermal expansion of the third inorganic layer A30. The inorganic layers A10, A20, and A30 adjacent to each other in the crystal layer CL according to an embodiment have respectively different coefficients of thermal expansion, and thus it is possible to achieve the effect of thermally strengthening the glass substrate GL including the crystal layer CL according to an embodiment.

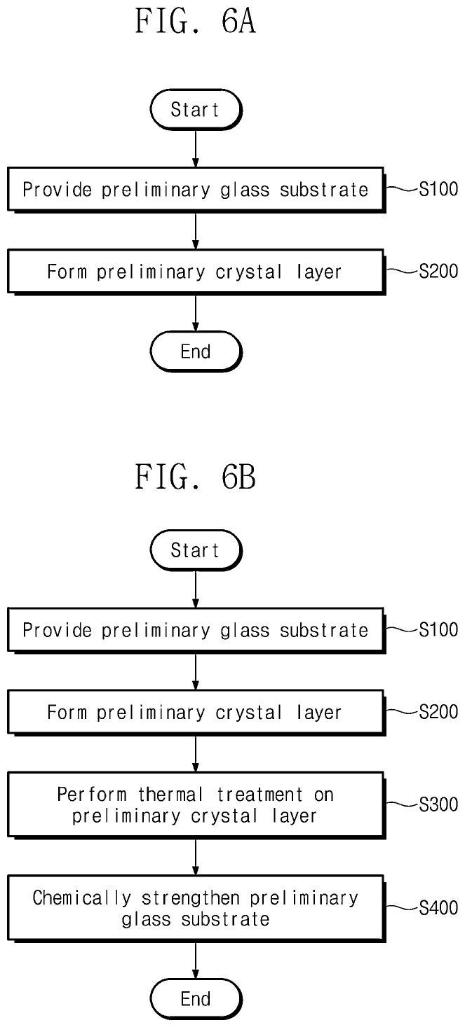

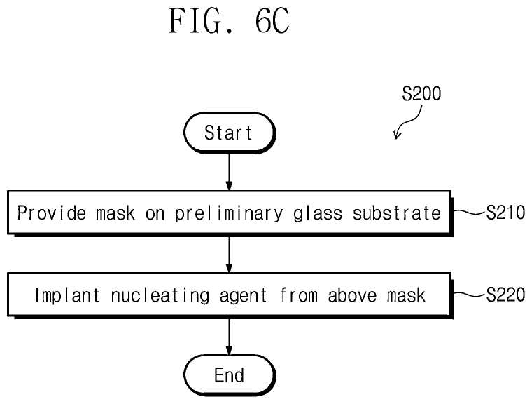

Hereinafter, a method of manufacturing the above-described window according to an embodiment of the invention will be illustrated with reference to FIGS. 6A to 6C, FIGS. 7A to 7C, and FIGS. 8A and 8B. In the description of the method of manufacturing the window according to an embodiment, the same or like elements as those described above will be omitted or simplified and the following description will be mainly focused on the differences.

FIGS. 6A and 6B are flowcharts illustrating a method of manufacturing a window according to an embodiment. FIG. 6C is a flowchart illustrating an operation of forming a preliminary crystal layer in the method of manufacturing the window according to an embodiment.

Referring to FIG. 6A, the method of manufacturing the window according to an embodiment of the invention may include providing (or preparing) a preliminary glass substrate (S100) and forming a preliminary crystal layer (S200). Referring to FIG. 6B, in an embodiment, the method of manufacturing the window may further include, after the forming of the preliminary crystal layer (S200), performing a heat treatment on the preliminary crystal layer (S300), and chemically strengthening the preliminary glass substrate (S400). Referring to FIG. 6C, in the method of manufacturing the window according to an embodiment, the forming of the preliminary crystal layer (S200) may include providing a mask above the preliminary glass substrate (S210) and implanting a nucleating agent from above the mask (S220).

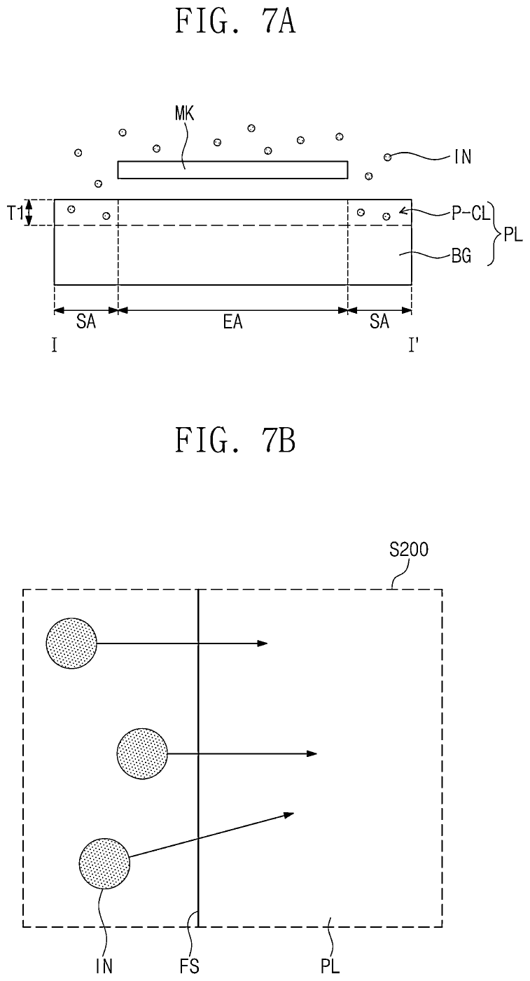

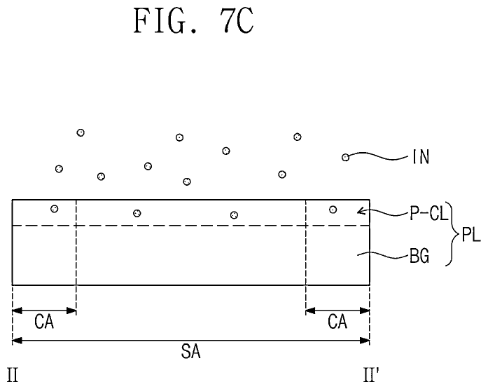

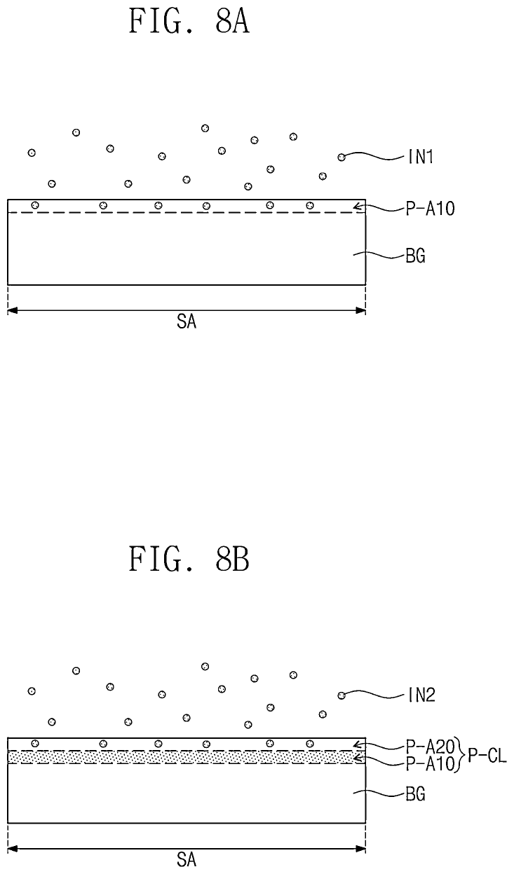

FIGS. 7A to 7C and FIGS. 8A and 8B are cross-sectional views of some operations of a method of manufacturing a window according to an embodiment. FIGS. 7A to 7C and FIGS. 8A and 8B schematically illustrate some operations of a method of manufacturing a window according to an embodiment of the invention. More particularly, FIG. 7A is a view illustrating an operation in a method of manufacturing the window and taken along line I-I′ of FIG. 4 described above, and FIG. 7B is a view illustrating an operation in a method of manufacturing the window and taken along line II-II′ of FIG. 4 described above.

Referring to FIGS. 7A and 7B, the method of manufacturing the window according to an embodiment of the invention may include providing (or preparing) a preliminary glass substrate PL. The preliminary glass substrate PL may include a central region EA, and an exterior region SA surrounding the central region EA. The preliminary glass substrate PL may include a base glass BG. In the providing of the preliminary glass substrate PL, the preliminary glass substrate PL may be manufactured through a float process, a down draw process, a fusion process, or the like. However, an embodiment of the invention is not limited thereto, and the preliminary glass substrate PL to be provided may be manufactured through another one of various methods not illustrated herein.

Referring to FIGS. 7A to 7C, the method of manufacturing the window according to an embodiment of the invention includes forming a preliminary crystal layer P-CL.

The preliminary crystal layer P-CL may be formed adjacent to an upper surface of the preliminary glass substrate PL. The preliminary crystal layer P-CL may be included in (or defined by a portion of) the preliminary glass substrate PL. Referring to FIG. 7A, the preliminary crystal layer P-CL may be formed to overlap the exterior region SA. Referring to FIG. 7C, the preliminary crystal layer P-CL may be formed to overlap corner regions CA.

The forming of the preliminary crystal layer P-CL includes implanting a nucleating agent IN into the preliminary glass substrate PL. The nucleating agent IN may include at least one selected from P₂O₅, ZrO₂, and TiO₂. Not only P₂O₅, ZrO₂, and TiO₂, but also any material which functions to be capable of accelerating crystal nucleation in the preliminary glass substrate PL may be used for the nucleating agent IN without any limitation.

The nucleating agent IN may be implanted into the preliminary glass substrate PL overlapping the exterior region SA in the preliminary glass substrate PL. The nucleating agent IN may be not implanted into the preliminary glass substrate PL in the central region EA, and be implanted only into the preliminary glass substrate PL in the exterior region SA. The preliminary crystal layer P-CL may be formed to overlap only the exterior region SA by using a mask MK. In an embodiment, the forming of the preliminary crystal layer P-CL may include providing the mask MK above the preliminary glass substrate PL in the central region EA and implanting the nucleating agent IN from above the mask MK, that is, toward the preliminary glass substrate through the mask MK. In the method of manufacturing the window according to an embodiment, the mask MK is disposed to overlap only the central region EA, such that the nucleating agent IN may be not implanted into the preliminary glass substrate PL in the central region EA and be implanted only into the preliminary glass substrate PL in the exterior region SA.

In the forming of the preliminary crystal layer P-CL, the nucleating agent IN may be implanted into the preliminary glass substrate PL through ion implantation. Referring to FIG. 7B, the nucleating agent IN may reach an upper surface FS of the preliminary glass substrate PL in an accelerated state by an ion accelerator or the like and be implanted into the preliminary glass substrate PL. Accordingly, the nucleating agent IN may be implanted to overlap only some regions. In an embodiment, for example, the nucleating agent IN may be implanted into the preliminary glass substrate PL to overlap only the exterior region SA. In addition, since the nucleating agent IN is implanted through ion implantation, the implantation depth, concentration, or the like, of the nucleating agent IN may be adjusted. The nucleating agent IN may be implanted to a predetermined depth from the upper surface FS of the preliminary glass substrate PL in a thickness direction. In an embodiment, for example, the preliminary crystal layer P-CL formed by implanting the nucleating agent IN may have a thickness T1 in a range of about 20 μm to about 100 μm.

The method of manufacturing the window according to an embodiment may further include, after the forming of the preliminary crystal layer P-CL, performing a heat treatment on the preliminary crystal layer P-CL (S300). In the method of manufacturing the window according to an embodiment, the performing of the heat treatment on the preliminary crystal layer P-CL may include crystallizing, by the nucleating agent IN, a material included in the preliminary glass substrate PL. In an embodiment, the performing of the heat treatment on the preliminary crystal layer P-CL may include forming a crystal nucleus using the nucleating agent IN at a predetermined temperature and growing a crystal. In the method of manufacturing the window according to an embodiment, the performing of the heat treatment on the preliminary crystal layer P-CL may be performed at a high temperature. In an embodiment, for example, the performing of the heat treatment on the preliminary crystal layer P-CL may be carried out at a temperature in a range of about 600° C. to about 1200° C. In an embodiment, the crystal particle size in the preliminary crystal layer P-CL may be adjusted according to conditions such as a heat treatment temperature for the preliminary crystal layer P-CL. Therefore, the durability of the window WM according to an embodiment of the invention (see FIG. 3) may be improved, and if necessary, the coefficient of thermal expansion of the preliminary crystal layer P-CL according to an embodiment of the invention may be adjusted. The glass substrate, which is manufactured through the forming of the preliminary crystal layer P-CL and the performing of the heat treatment on the preliminary crystal layer P-CL, may include the crystal layer CL (see FIG. 5A) on an upper surface thereof.

The method of manufacturing the window according to an embodiment of the invention may further include, after the forming of the preliminary crystal layer P-CL, chemically strengthening the preliminary glass substrate PL (S400). The chemically strengthening of the preliminary glass substrate PL may include providing a strengthening molten salt to the preliminary glass substrate PL to increase the surface strength of the preliminary glass substrate PL through ion exchange. The chemically strengthening of the preliminary glass substrate PL may include strengthening a surface thereof through an ion-exchange process. In an embodiment, for example, the chemically strengthening of the preliminary glass substrate PL through the ion-exchange process may be performed by exchanging, on a surface of the preliminary glass substrate PL, alkali metal ions having a relatively smaller ionic radius with alkali metal ions having a larger ionic radius. In the chemically strengthening of the preliminary glass substrate PL, a single salt including one ion selected from LiF⁺, Na⁺, KC⁺, Rb⁺, and Cs⁺ may be included in the strengthening molten salt. Alternatively, in the chemically strengthening of the preliminary glass substrate PL, a mixed salt including two kinds of ions selected from Li⁺, Na⁺, K⁺, Rb⁺, and Cs⁺ may be included in the strengthening molten salt. The glass substrate, which is manufactured through the chemically strengthening process, may include the above-described compressive stress layer on an upper surface thereof.

Referring to FIGS. 8A and 8B, the forming of the preliminary crystal layer P-CL in a method of manufacturing a window according to an alternative embodiment may include forming a first preliminary inorganic layer P-A10 and forming a second preliminary inorganic layer P-A20.

The forming of the preliminary crystal layer P-CL in the method of manufacturing the window according to an embodiment of the invention may include forming a plurality of layers. In an embodiment, for example, the forming of the preliminary crystal layer P-CL may include forming the first preliminary inorganic layer P-A10 by implanting a first nucleating agent IN1 into the preliminary glass substrate PL. The method of manufacturing the window according to an embodiment may further include, after the forming of the first preliminary inorganic layer P-A10, forming the second preliminary inorganic layer P-A20 by implanting a second nucleating agent IN2 into the first preliminary inorganic layer P-A10.

The preliminary crystal layer P-CL may include the first preliminary inorganic layer P-A10 and the second preliminary inorganic layer P-A20. The first preliminary inorganic layer P-A10 and the second preliminary inorganic layer P-A20 may overlap only the exterior region SA. The first preliminary inorganic layer P-A10 and the second preliminary inorganic layer P-A20 may be each formed to overlap only the exterior region SA by using the mask MK (see FIG. 7A) overlapping or covering the central region EA. The coefficient of thermal expansion of the first preliminary inorganic layer P-A10 may be different from the coefficient of thermal expansion of the second preliminary inorganic layer P-A20. The material included in the first preliminary inorganic layer P-A10 may be different from the material included in the second preliminary inorganic layer P-A20. The first nucleating agent IN1 and the second nucleating agent IN2 may each independently include at least one selected from P₂O₅, ZrO₂, and TiO₂.

As described above, a window according to an embodiment includes a crystal layer in an exterior region to improve the strength of the window in the exterior region vulnerable to breakage, and thus have the improved impact resistance. Therefore, the window according to an embodiment may have the improved reliability and stability. Also, a method of manufacturing a window according to an embodiment includes forming a crystal layer through ion implantation. Accordingly, in the method of manufacturing the window according to an embodiment, a nucleating agent may be provided only to a partial region of the glass substrate of the window, and thus only the partial region of the glass substrate of the window may be crystallized. In the method of manufacturing the window according to an embodiment, the nucleating agent is provided only to a window exterior region vulnerable to breakage in the glass substrate to achieve crystallization strengthening, thereby making it possible to manufacture the window with the improved reliability and stability. That is, in the method of manufacturing the window according to an embodiment, an additional crystallization process is performed on a region vulnerable to breakage, and thus the window with the improved durability may be manufactured. In addition, in the method of manufacturing the window according to an embodiment, the window with the improved reliability and stability may be manufactured by performing thermal strengthening and chemical strengthening treatments as well as a glass strengthening treatment through partial crystallization.

A window according to an embodiment may exhibit improved strength.

A method of manufacturing a window according to an embodiment includes forming a crystal layer through ion implantation, and thus the window with the improved strength according to an embodiment may be manufactured through the method of manufacturing the window according to an embodiment.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A window comprising:
a base glass including a central region, and an exterior region surrounding the central region; and
a crystal layer disposed on the base glass and overlapping the exterior region,
wherein the crystal layer includes at least one selected from P₂O₅, ZrO₂, and TiO₂, and
a crystal content of the base glass is different from a crystal content of the crystal layer.

2. The window of claim 1, wherein the crystal layer does not overlap the central region.

3. The window of claim 1, wherein the crystal content of the crystal layer is greater than the crystal content of the base glass.

4. The window of claim 1, wherein a coefficient of thermal expansion of the base glass is different from a coefficient of thermal expansion of the crystal layer.

5. The window of claim 1, wherein
the exterior region comprises a corner region adjacent to a vertex of the central region, and
the crystal layer overlaps the corner region.

6. The window of claim 1, wherein the crystal layer has a thickness in a range of about 20 μm to about 100 μm.

7. The window of claim 1, wherein the crystal layer comprises:
a first inorganic layer disposed on the base glass; and
a second inorganic layer disposed on the first inorganic layer,
wherein a coefficient of thermal expansion of the first inorganic layer is different from a coefficient of thermal expansion of the second inorganic layer.

8. The window of claim 7, wherein
the crystal layer further comprises a third inorganic layer disposed on the second inorganic layer, and
a coefficient of thermal expansion of the third inorganic layer is different from a coefficient of thermal expansion of the second inorganic layer.

9. The window of claim 1, further comprising:
a bezel pattern disposed under the base glass; and
a window functional layer disposed on the base glass to cover the crystal layer.

10. The window of claim 9, wherein the bezel pattern overlaps the exterior region.

11. The window of claim 1, wherein the window has a light transmittance in a range of about 80% to about 100% with respect to light in a wavelength range of about 400 nm to about 700 nm.

12. A method of manufacturing a window, the method comprising:
providing a preliminary glass substrate including a central region and an exterior region surrounding the central region; and
forming a preliminary crystal layer by implanting a nucleating agent into the preliminary glass substrate through ion implantation,
wherein the preliminary crystal layer overlaps the exterior region, and
the nucleating agent includes at least one selected from P₂O₅, ZrO₂, and TiO₂.

13. The method of claim 12, wherein the forming the preliminary crystal layer comprises:
providing a mask over the preliminary glass substrate to cover the central region; and
implanting the nucleating agent from above the mask.

14. The method of claim 12, wherein
the exterior region comprises a corner region adjacent to a vertex of the central region, and
the preliminary crystal layer overlaps the corner region.

15. The method of claim 12, further comprising, after the forming the preliminary crystal layer, performing a thermal treatment on the preliminary crystal layer.

16. The method of claim 12, wherein the preliminary crystal layer has a thickness in a range of about 20 μm to about 100 μm from an upper surface of the preliminary glass substrate.

17. The method of claim 12, wherein the forming the preliminary crystal layer comprises:
forming a first preliminary inorganic layer by implanting, into the preliminary glass substrate, a first nucleating agent including at least one selected from P₂O₅, ZrO₂, and TiO₂; and
forming a second preliminary inorganic layer by implanting, into the first preliminary inorganic layer, a second nucleating agent including at least one selected from P₂O₅, ZrO₂, and TiO₂.

18. The method of claim 17, wherein a coefficient of thermal expansion of the first preliminary inorganic layer is different from a coefficient of thermal expansion of the second preliminary inorganic layer.

19. The method of claim 12, further comprising, after the forming the preliminary crystal layer, chemically strengthening the preliminary glass substrate.

20. The method of claim 12, wherein the chemically strengthening the preliminary glass substrate includes providing a strengthening molten salt to the preliminary glass substrate.
